(19) United States
(12) Patent Application Publication
(10) Pub. No.: US 2015/0069554 A1
(43) Pub. Date: Mar. 12, 2015

(54) MAGNETIC MEMORY AND METHOD OF MANUFACTURING THE SAME

(71) Applicants: Masahiko NAKAYAMA, Seoul (KR); Yasuyuki SONODA, Seoul (KR); Hiroaki YODA, Seoul (KR); Makoto NAGAMINE, Seoul (KR); Masatoshi YOSHIKAWA, Seoul (KR); Masaru TOKO, Seoul (KR); Tadashi KAI, Seoul (KR); Daisuke WATANABE, Seoul (KR); Youngmin EEH, Seoul (KR); Koji UEDA, Seoul (KR); Kazuya SAWADA, Seoul (KR); Toshihiko NAGASE, Seoul (KR)

(72) Inventors: Masahiko NAKAYAMA, Seoul (KR); Yasuyuki SONODA, Seoul (KR); Hiroaki YODA, Seoul (KR); Makoto NAGAMINE, Seoul (KR); Masatoshi YOSHIKAWA, Seoul (KR); Masaru TOKO, Seoul (KR); Tadashi KAI, Seoul (KR); Daisuke WATANABE, Seoul (KR); Youngmin EEH, Seoul (KR); Koji UEDA, Seoul (KR); Kazuya SAWADA, Seoul (KR); Toshihiko NAGASE, Seoul (KR)

(21) Appl. No.: 14/201,263

(22) Filed: Mar. 7, 2014

Related U.S. Application Data
(60) Provisional application No. 61/874,645, filed on Sep. 6, 2013.

(51) Int. Cl. H01L 43/02; H01L 43/12

(52) U.S. Cl. CPC H01L 43/02; H01L 43/12
USPC 257/421; 438/3

(57) ABSTRACT

According to one embodiment, a magnetic memory is disclosed. The memory includes a conductive layer containing a first metallic material, a stacked body formed above the conductive layer and including a first magnetic layer containing a second metallic material, a second magnetic layer, and a tunnel barrier layer formed between the first magnetic layer and the second magnetic layer, and an insulating layer formed on a side face of the stacked body and containing an oxide of the first metallic material. A standard electrode potential of the first metallic material is lower than the standard electrode potential of the second metallic material.

### CROSS-REFERENCE TO RELATED APPLICATIONS

This application claims the benefit of U.S. Provisional Application No. 61/874,645, filed Sep. 6, 2013, the entire contents of which are incorporated herein by reference.

### FIELD

Embodiments described herein relate generally to a magnetic memory and a method of manufacturing the same.

### BACKGROUND

MRAM (Magnetic Random Access Memory) is a memory device using a storage element having a magnetoresistive effect for a memory cell that stores information. MRAM attracts attention as a next-generation memory device featuring the high-speed operation, large capacity, and non-volatility.

The magnetoresistive effect is a phenomenon in which electric resistance changes in accordance with the magnetization direction of a ferromagnetic substance. In MRAM, the magnetization direction of such a ferromagnetic substance is used to record information and information is read based on the magnitude of electric resistance corresponding thereto. Accordingly, MRAM can be caused to operate as a memory device.

In recent years, a ferromagnetic tunnel junction including two CoFeB ferromagnetic layers and an MgO tunnel barrier layer formed therebetween is used in a magnetoresistive effect element. In the ferromagnetic tunnel junction, a huge MR (Magnetic Resistance) ratio of 100% or more can be obtained due to the TMR (Tunnel Magnetic Resistance) effect. Thus, large-capacity MRAM using an MTJ (Magnetic Tunnel Junction) element making use of the TMR effect attracts expectations and attention as a magnetoresistive effect element.

When an MTJ element is used to MRAM, one of two ferromagnetic layers sandwiching the tunnel barrier layer therebetween is set as a reference layer in which the magnetization direction is invariable and the other is set as a storage layer in which the magnetization direction is variable. Information can be stored by associating a state in which the magnetization direction of the reference layer and the magnetization direction of the storage layer are parallel and a state in which both magnetization directions are antiparallel with “0” and “1”. When compared with a case in which both magnetization directions are antiparallel, the resistance (barrier resistance) of the tunnel barrier layer is smaller and the tunnel current is larger when both magnetization directions are parallel.

### BRIEF DESCRIPTION OF THE DRAWINGS

FIG. 1 is a circuit diagram showing a memory cell array of MRAM according to a first embodiment;

FIG. 2 is a plan view showing the memory cell array of MRAM according to the first embodiment;

FIG. 3 is a sectional view along an A-A′ line in FIG. 2;

FIG. 4A is a sectional view showing an outline configuration of a magnetoresistive effect element;

FIG. 4B is a diagram illustrating a write operation of the magnetoresistive effect element and is a diagram showing a sectional view of the magnetoresistive effect element in a parallel state;

FIG. 4C is a diagram illustrating the write operation of the magnetoresistive effect element and is a diagram showing a sectional view of the magnetoresistive effect element in an antiparallel state;

FIG. 5 is a sectional view showing the configuration of the magnetoresistive effect element according to the first embodiment;

FIG. 6 is a graph showing standard electrode potentials of various metallic materials;

FIG. 7 is a graph showing shunt bit rates of various metallic materials;

FIGS. 8, 9, 10, 11, and 12 are sectional views showing manufacturing processes of the magnetoresistive effect element according to the first embodiment;

FIG. 13 is a sectional view showing the configuration of a modification of the magnetoresistive effect element according to the first embodiment;

FIG. 14 is a sectional view showing the configuration of the magnetoresistive effect element according to a second embodiment;

FIGS. 15, 16, 17, 18, and 19 are sectional views showing manufacturing processes of the magnetoresistive effect element according to the second embodiment;

FIG. 20 is a graph showing a relationship between a dielectric constant and a breakdown field of various oxides;

FIGS. 21A and 21B are sectional views illustrating the thickness of a tunnel barrier layer 43; and

FIG. 22 is a diagram showing the dielectric constants and breakdown fields of various oxides.

### DETAILED DESCRIPTION

In general, according to one embodiment, a magnetic memory is disclosed. The memory includes a conductive layer containing a first metallic material; a stacked body formed above the conductive layer and comprising a first magnetic layer containing a second metallic material, a second magnetic layer, and a tunnel barrier layer formed between the first magnetic layer and the second magnetic layer; and an insulating layer formed on a side face of the stacked body and containing an oxide of the first metallic material, A standard electrode potential of the first metallic material is lower than the standard electrode potential of the second metallic material.

In an MRAM manufacturing process, an MTJ film that shows the TMR effect is stacked on an electrode (for example, a contact plug) and the MTJ film is selectively etched to form an MTJ element. At this point, re-deposition of processing residue is occurred on the side face of the MTJ element. The processing residue is mainly material of the layer processed last and re-deposited. If a conductive processing residue is re-deposited near the tunnel barrier layer on the side face of the MTJ element, a short fault occurs between upper and lower ferromagnetic layers of the tunnel barrier layer. If the short fault occurs, the amount of current passing between the upper and lower ferromagnetic layers without passing through the tunnel barrier layer increases. As a result, the ratio of resistance changes reflecting a difference of barrier resistance between the parallel state and the antiparallel state of the magnetization direction decreases, leading to a smaller MR ratio.

As a countermeasure to prevent the short fault due to the processing residue, re-depositing an insulating processing residue or selecting processing conditions under which no processing residue is re-deposited can be considered.

However, to re-deposit an insulating processing residue on the side face of an MTJ element, after processing the conductive layer directly below the tunnel barrier layer, it is necessary to continue the processing down to an interlayer dielectric layer positioned further below. Thus, etching needs to be performed for a long time, which is hard to implement from the viewpoint of controlling dimensions of the MTJ element and shortening the processing time. The processing conditions for re-depositing no processing residue requires processing a sidewall of the MTJ element by active species which is capable of etching the sidewall, thus an edge (side face portion) of the tunnel barrier layer is damaged, and resulting in the short fault.

On the other hand, as the other countermeasure to prevent the short fault due to the processing residue, oxidizing the re-deposits to give insulating properties can be considered. However, if a strong oxidation process is needed to convert the re-deposits into insulating materials, up to the edge (side face portion) of the ferromagnetic layer will be oxidized. Damage due to oxidation of the ferromagnetic layer causes problems such as degradation of the MR ratio.

In the present embodiment, by contrast, the above problem is solved by constituting the re-deposit with metallic material whose standard electrode potential is small.

The present embodiment will be described below with reference to the drawings. The same reference numerals are attached to the same portions in the drawings. In addition, a duplicate description is provided when necessary.

### First Embodiment

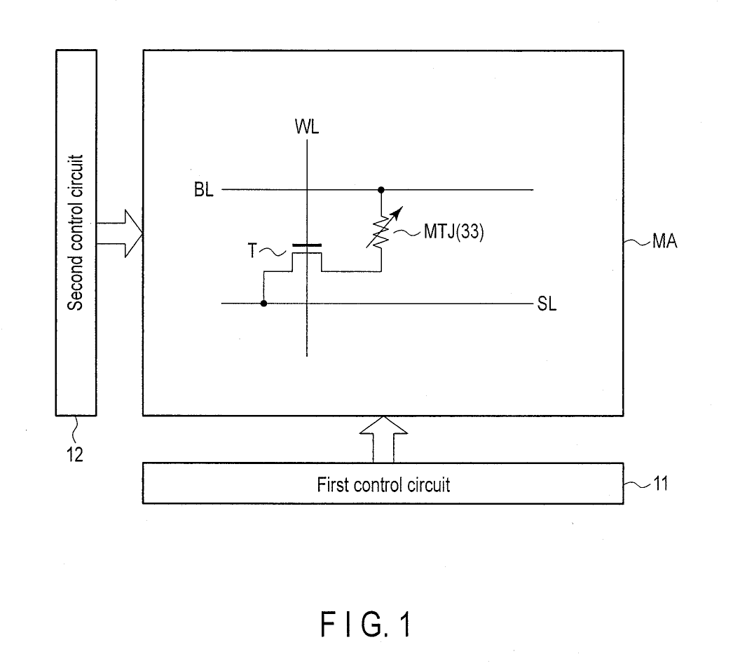

MRAM according to the first embodiment will be described below using FIGS. 1 to 12. In MRAM according to the first embodiment, a lower electrode 32 positioned below a stacked body includes a storage layer 42, the tunnel barrier layer 43, and a reference layer 44 contains a first metallic material having a standard electrode potential smaller than that of any metallic material contained in the storage layer 42 and the reference layer 44. Thereby, even if a processing residue of the lower electrode 32 is re-deposited on the side face of a stacked body, the re-deposit can easily be oxidized. The first embodiment will be described in detail below.

[Basic Configuration Example of MRAM According to the First Embodiment]

A basic configuration example of MRAM according to the first embodiment will be described using FIG. 1 to FIG. 4.

FIG. 1 is a circuit diagram showing a memory cell array of MRAM according to the first embodiment.

As shown in FIG. 1, a memory cell in a memory cell array MA comprises a serially connected body of a magnetoresistive effect element 33 and a switch element (for example, FET) T. One end of the serially connected body (one end of the magnetoresistive effect element 33) is electrically connected to a bit line BL and the other end (one end of the switch element T) of the serially connected body is electrically connected to a source line SL. A control terminal of the switch terminal T, for example, a gate electrode of FET is electrically connected to a word line WL.

The potential of the word line WL is controlled by a first control circuit 11. The potentials of the bit line BL and the source line SL are controlled by a second control circuit 12.

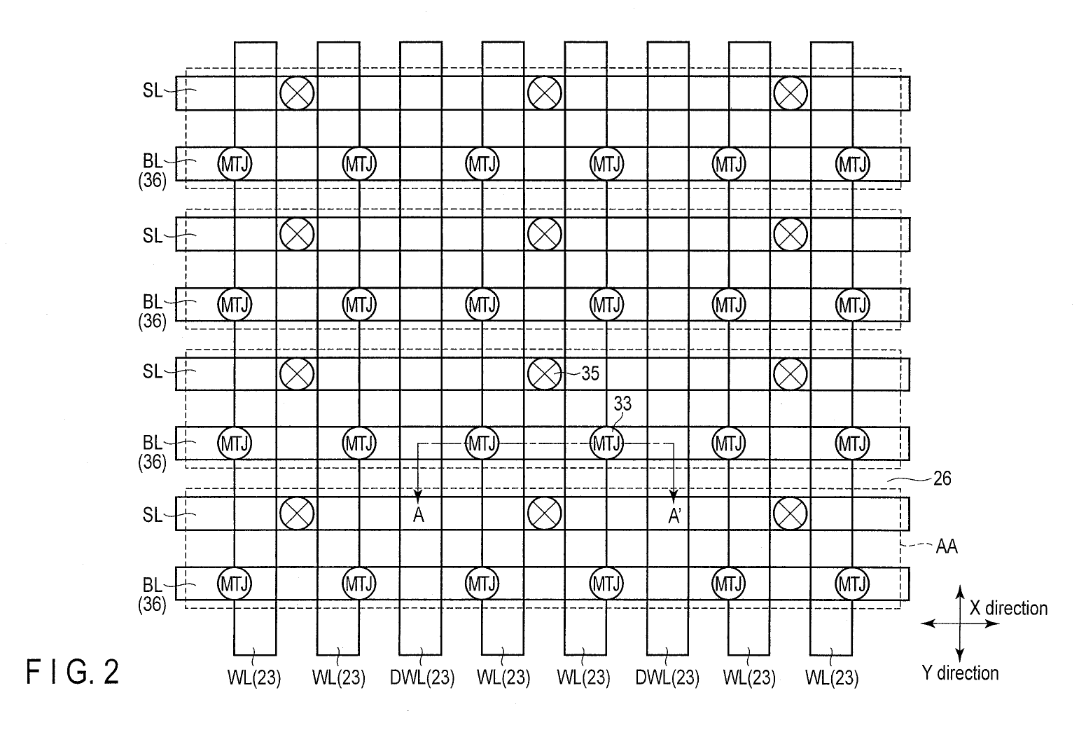

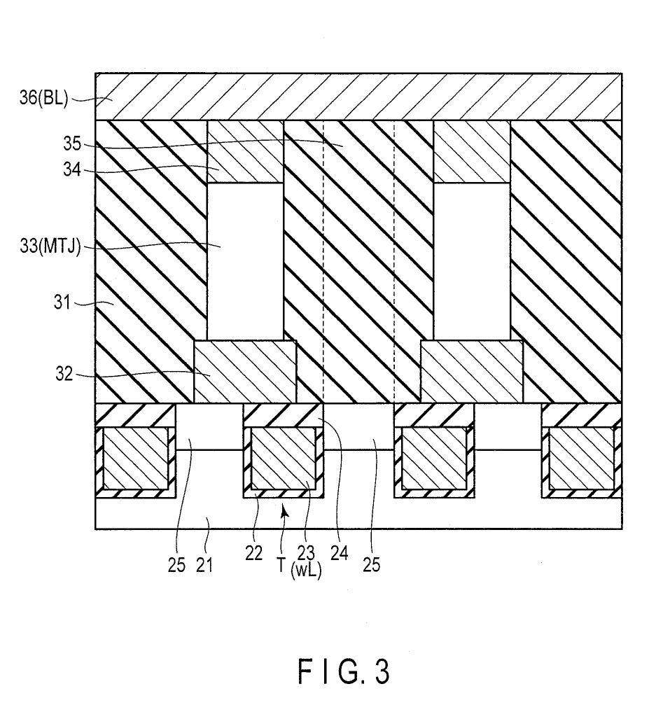

FIG. 2 is a plan view showing the memory cell array of MRAM according to the first embodiment. FIG. 3 is a sectional view along an A-A′ line in FIG. 2. FIG. 3 also shows a cross section of a source line contact 35 together with the cross section of the magnetoresistive effect element 33.

As shown in FIGS. 2 and 3, as an example, a plurality of word lines WL and a plurality of dummy word lines DWL extending in a Y direction and a plurality of bit lines BL and a plurality of source lines SL extending in an X direction perpendicular to the Y direction are arranged in the memory cell array MA. Two word lines WL and one dummy word line DWL are alternately arranged along the X direction. The bit line BL and the source line SL are alternately arranged along the Y direction.

In addition, a device isolation insulating layer extending in the X direction is provided in a surface region of a p-type semiconductor substrate (for example, a silicon substrate) 21 in the memory cell array MA and this region becomes an element isolation region 26. The surface region of the semiconductor substrate 21 in which the element isolation insulating layer is not provided becomes an active area AA. That is, the element isolation region 26 and the active area AA are alternately formed along the Y direction. The element isolation insulating layer is formed of, for example, STI (Shallow Trench Isolation). As the element isolation insulating layer, an insulating material having a high filling characteristic such as silicon nitride (SiN) is used.

As shown in FIG. 3, a select transistor using, for example, an n-channel MOSFET (Metal Oxide Semiconductor Field Effect Transistor) is provided on a semiconductor substrate 21 as the switch element T. The select transistor has a structure in which a recess is formed in the semiconductor substrate 21 and the gate electrode 23 containing, for example, polycrystalline silicon is embedded in this recess.

More specifically, a select transistor T includes a gate insulating layer 22, the gate electrode 23, and two diffusion layers 25 (a drain-side diffusion layer and a source-side diffusion layer).

The gate insulating layer 22 is formed on an inner surface on the lower side of a recess extending in the Y direction formed on the surface of the semiconductor substrate 21. The gate electrode 23 is formed on the inner surface of the gate insulating layer 22 like filling in the lower side of the recess. This gate electrode 23 corresponds to the word line WL. An insulating layer 24 made of, for example, SiN is formed on top surfaces of the gate insulating layer 22 and the gate electrode 23 like filling in an upper side of the recess. The top surface of the insulating layer 24 is approximately as high as the top surface (top surface of the diffusion layers 25 described later) of the semiconductor substrate 21.

The two diffusion layers 25 are formed in the surface of the semiconductor substrate 21 like sandwiching the gate insulating layer 22, the gate electrode 23, and the insulating layer 24 therebetween. The diffusion layers 25 positioned between two neighboring memory cells along the X direction are shared by the two neighboring memory cells. On the other hand, the diffusion layers 25 are isolated by the element isolation region 26 along the Y direction. In other words, the two diffusion layers 25 adjacent along the Y direction are adjacent via the element isolation region 26. That is, the diffusion layers 25 are positioned outside the formation region of the gate insulating layer 22, the gate electrode 23, and the insulating layer 24 in the active area AA. An interlayer dielectric layer 31 is formed on the semiconductor substrate 21 (on the insulating layer 24 and the diffusion layer 25).

A lower electrode 32, a magnetoresistive effect element 33, and an upper electrode 34 are formed in this order on one of the diffusion layers 25 (drain-side diffusion layer) inside the interlayer dielectric layer 31.

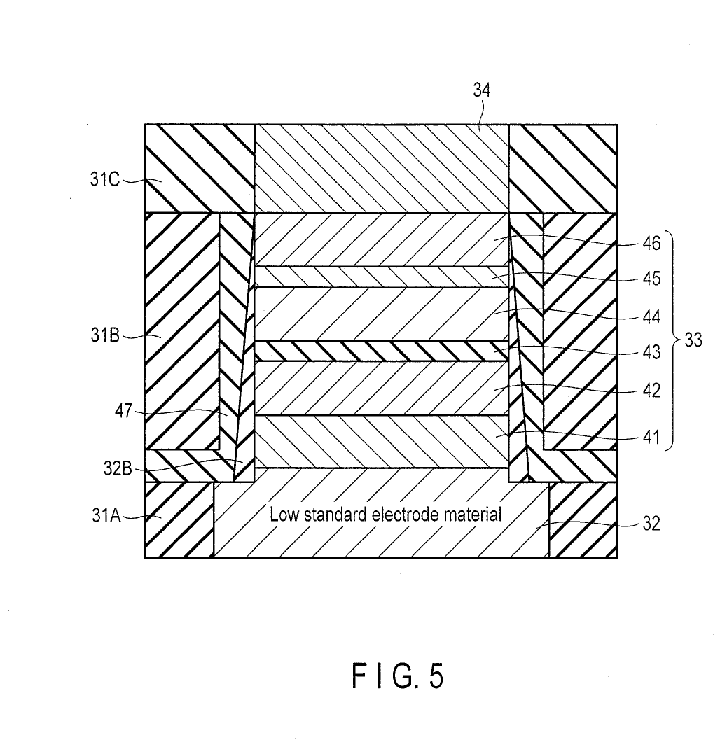

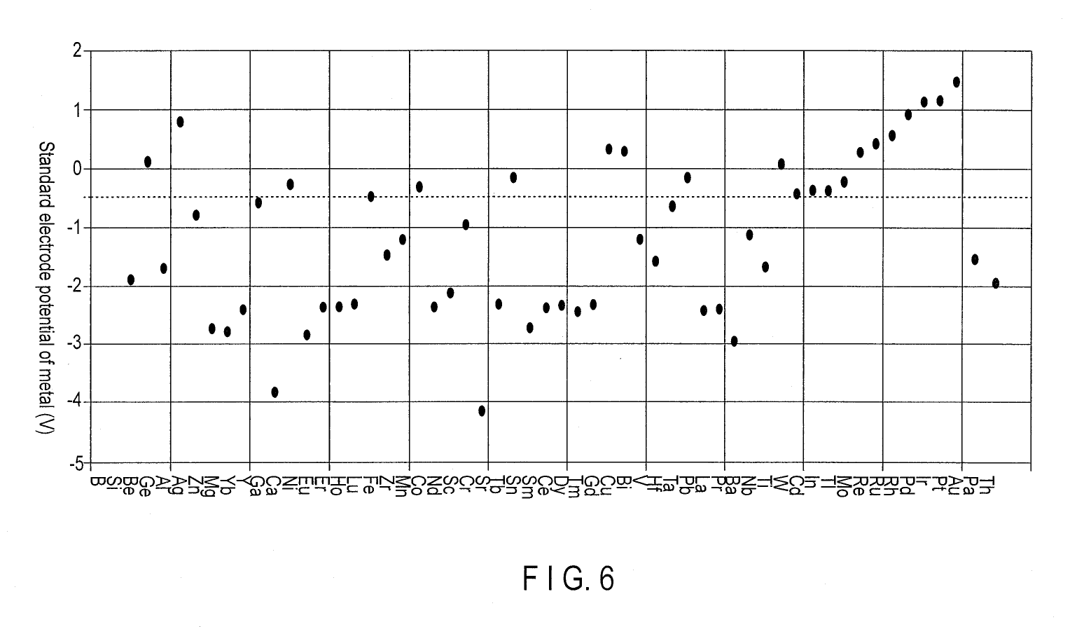

More specifically, the lower electrode 32 is formed so as to be in contact with a portion of the top surface of one of the diffusion layers 25 (drain-side diffusion layer) and a portion of the top surface of the insulating layer 24. In other words, the lower electrode 32 and the diffusion layer 25 partially overlap in a plane. This is because the processing method of the lower electrode 32 and that of the diffusion layer 25 (recess) are different. The plane shape of the interlayer dielectric layer 31 is, for example, square. Details of the lower electrode 32 will be described later using FIGS. 5 and 6.

The magnetoresistive effect element 33 is formed so as to be in contact with the top surface of the lower electrode 32. The magnetoresistive effect element 33 has, for example, a circular plane shape and is formed in a cylindrical shape. In other words, the magnetoresistive effect element 33 and a lower electrode 49a overlap in a plane. It is desirable that the plane area of the magnetoresistive effect element 33 be smaller than the plane area of the lower electrode 32. Thereby, the whole bottom surface of the magnetoresistive effect element 33 can be in contact with the top surface of the lower electrode 32, and reducing the contact resistance thereof.

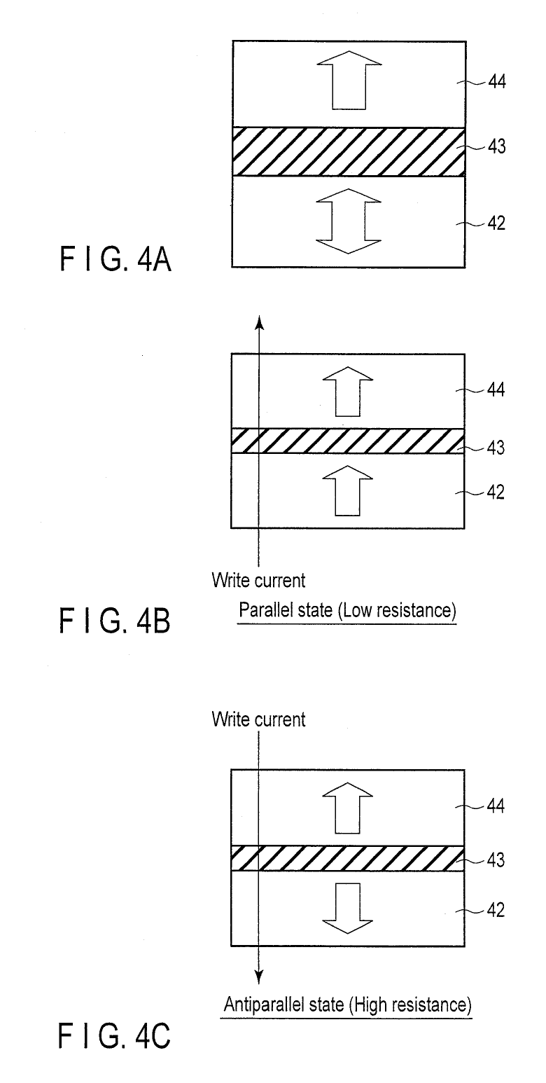

FIG. 4A is a sectional view showing an outline configuration of a magnetoresistive effect element. Here, the storage layer 42, the tunnel barrier layer 43, and the reference layer 44 are mainly shown as the magnetoresistive effect element 33.

As shown in FIG. 4A, the magnetoresistive effect element 33 contains a stacked body comprising the storage layer 42 that is a ferromagnetic (may simply be called magnetic) layer, the reference layer 44 that is a ferromagnetic layer, and the tunnel barrier layer 43 that is a nonmagnetic layer formed therebetween.

The storage layer 42 is a ferromagnetic layer in which the magnetization direction is variable and has a perpendicular magnetic anisotropy that is perpendicular or approximately perpendicular to the film surface (top surface/bottom surface). Here, the magnetization direction is variable indicates that the magnetization direction changes for a predetermined write current. In addition, Being approximately perpendicular means that the direction of residual magnetization is in the range of 45°<θ≦90° with respect to the film surface.

The tunnel barrier layer 43 is formed on the storage layer 42. The tunnel barrier layer 43 is a nonmagnetic layer and is formed of, for example, MgO.

The reference layer 44 is formed on the tunnel barrier layer 43. The reference layer 44 is a ferromagnetic layer in which the magnetization direction is invariable, and has a perpendicular magnetic anisotropy that is perpendicular or approximately perpendicular to the film surface. Here, the magnetization direction is invariable indicates that the magnetization direction does not change for a predetermined write current. That is, the reference layer 44 has a larger reversal energy barrier than the storage layer 42.

FIG. 4B is a diagram illustrating a write operation of the magnetoresistive effect element and is a diagram showing a sectional view of the magnetoresistive effect element in a parallel state. FIG. 4C is a diagram illustrating the write operation of the magnetoresistive effect element and is a diagram showing a sectional view of the magnetoresistive effect element in an antiparallel state.

The magnetoresistive effect element 33 is, for example, a spin injection type magnetoresistive effect element. Thus, when data is written into the magnetoresistive effect element 33 or data is read from the magnetoresistive effect element 33, a current is passed to the magnetoresistive effect element 33 bidirectionally in a direction perpendicular to the film surface.

More specifically, data is written into the magnetoresistive effect element 33 as described below.

As shown In FIG. 4B, When a current flows from the lower electrode 32 to the upper electrode 34, that is, electrons (electrons from the reference layer 44 to the storage layer 42) are supplied from the side of the upper electrode 34, electrons spin-polarized in the same direction as the magnetization direction of the reference layer 44 are injected into the storage layer 42. In this case, the magnetization direction of the storage layer 42 is aligned with the same direction as the magnetization direction of the reference layer 44. Thereby, the magnetization direction of the reference layer 44 and the magnetization direction of the storage layer 42 are parallel arrays. In this parallel state, the value of resistance of the magnetoresistive effect element 33 is the smallest. This case is defined as, for example, data “0”.

On the other hand, when, as shown in FIG. 4C, a current flows from the upper electrode 34 to the lower electrode 32, that is, when electrons (electrons from the storage layer 42 to the reference layer 44) are supplied from the side of the lower electrode 32, electrons spin-polarized in a direction opposite to the magnetization direction of the reference layer 44 injected into the storage layer 42 due to being reflected by the reference layer 44. Thereby, the magnetization direction of the reference layer 44 and the magnetization direction of the storage layer 42 are antiparallel arrays. In this antiparallel state, the value of resistance of the magnetoresistive effect element 33 is the largest. This case is defined as, for example, data “1”.

In addition, data is read from the magnetoresistive effect element 33 as described below.

A read current is supplied to the magnetoresistive effect element 33. This read current is set to a value (value smaller than the write current) at which the magnetization direction of the storage layer 42 is not reversed. The data “0” or “1” can be read by detecting changes of the value of resistance of the magnetoresistive effect element 33 at this point.

As shown in FIG. 3, the upper electrode 34 is formed so as to be in contact with the top surface of the magnetoresistive effect element 33. The bit line BL is formed on the upper electrode 34 so as to be in contact therewith. That is, the upper electrode 34 is a bit line contact.

In addition, a source line contact 35 is formed on the other diffusion layer 25 (source-side diffusion layer) inside the interlayer dielectric layer 31. The source line contact 35 is formed so as to be in contact with the top surface of the other diffusion layer 25. The source line SL is formed on this source line contact 35 so as to be in contact therewith. The other diffusion layer 25 and the source line contact 35 are shared by two neighboring memory cells.

Among the three gate electrodes 23 adjacent in the X direction, the two gate electrodes 23 are electrically connected to the magnetoresistive effect element 33 and correspond to the word like WL, and the one gate electrode 23 is not electrically connected to the magnetoresistive effect element 33 and corresponds to the dummy word line DWL.

[Configuration of the Magnetoresistive Effect Element According to the First Embodiment]

The configuration of the magnetoresistive effect element 33 according to the first embodiment will be described using FIGS. 5 to 7.

FIG. 5 is a sectional view showing the configuration of the magnetoresistive effect element according to the first embodiment. Here, in addition to the magnetoresistive effect element 33, the lower electrode 32 positioned below the magnetoresistive effect element 33 and the upper electrode 34 positioned above the magnetoresistive effect element 33 are also shown.

As shown in FIG. 5, MRAM comprises the lower electrode 32, the upper electrode 34, and the magnetoresistive effect element 33. The lower electrode 32 is formed in an interlayer dielectric layer 31A and the upper electrode 34 is formed in an interlayer dielectric layer 31C. The magnetoresistive effect element 33 is formed between the lower electrode 32 and the upper electrode 34, and an interlayer dielectric layer 32B is formed between the neighboring magnetoresistive effect elements 33.

The magnetoresistive effect element 33 comprises the underlying layer 41, the storage layer 42, the tunnel barrier layer 43, the reference layer 44, an intermediate layer 45, and a shift cancelling layer 46.

The underlying layer 41 is formed on the lower electrode 32. The underlying layer 41 contains a nonmagnetic material having electric conductivity.

The storage layer 42 is formed on the underlying layer 41. The storage layer 42 contains a ferromagnetic material like, for example, Co and Fe (second metallic material). In addition, B is added to the ferromagnetic material for the purpose of adjusting saturation magnetization or crystal magnetic anisotropy. That is, the storage layer 42 comprises a compound, for example, CoFeB or the like.

The tunnel barrier layer 43 is formed on the storage layer 42. The tunnel barrier layer 43 contains a nonmagnetic material, for example, MgO or the like. However, the present embodiment is not limited to such an example and the tunnel barrier layer 43 may contain metallic oxide such as Al₂O₃, MgAlO, ZnO, or TiO.

The reference layer 44 is formed on the tunnel barrier layer 43. The reference layer 44 comprises, for example, a laminated structure of a first magnetic layer, a nonmagnetic layer, and a second magnetic layer formed from the side of the tunnel barrier layer.

The first magnetic layer contains a ferromagnetic material like, for example, Co and Fe (second metallic material). B is added to the ferromagnetic material for the purpose of adjusting saturation magnetization or crystal magnetic anisotropy. That is, the first magnetic layer is formed of, for example, a compound such as CoFeB same as the storage layer 42. The first magnetic layer is a layer contributing to the MR ratio. The nonmagnetic layer is formed between the first magnetic layer and the second magnetic layer. The nonmagnetic layer contains a nonmagnetic material like Ta, W, or Hf. The second magnetic layer contains a ferromagnetic material and a nonmagnetic material. For example, Pt can be cited as the nonmagnetic material. As the ferromagnetic material, for example, Co is contained as a ferromagnetic material. That is, the second magnetic layer comprises a stacked film, for example, a Pt layer and a Co layer. This stacked film comprises a plurality of Pt layers and a plurality of Co layers being alternately stacked. The second magnetic layer contributes to perpendicular magnetic anisotropy.

The shift cancelling layer 46 is formed on the reference layer 44 via the intermediate layer 45. The intermediate layer 45 contains, for example, a nonmagnetic material having electric conductivity such as Ru. The shift cancelling layer 46 is a magnetic layer in which the magnetization direction is invariable and has a perpendicular magnetic anisotropy that is perpendicular or approximately perpendicular to the film surface. In addition, the magnetization direction thereof is a direction opposite to the magnetization direction of the reference layer 44. Thereby, the shift cancelling layer 46 can cancel out, a leakage magnetic field from the reference layer 44, which is applied to the storage layer 42. In other words, the shift cancelling layer 46 has an effect of adjusting, an offset of reversal characteristics for the storage layer 42 due to the leakage magnetic field from the reference layer 44, to the opposite direction. This shift cancelling layer 46 comprises, for example, an artificial lattice having a stacked structure of a ferromagnetic material like such as Ni, Fe, or Co and a nonmagnetic material such as Cu, Pd, or Pt. The upper electrode 34 is formed on the shift cancelling layer 46.

In addition, the plane shape of the underlying layer 41, the storage layer 42, the tunnel barrier layer 43, the reference layer 44, the intermediate layer 45, and the shift cancelling layer 46 is, for example, circular. Thus, the magnetoresistive effect element 33 is formed in a pillar shape. However, the present embodiment is not limited to such an example and the plane shape of the magnetoresistive effect element 33 may be square, rectangular, or elliptic.

In addition, the storage layer 42 and the reference layer 44 may have dimensional differences in a plane. For example, the diameter of the reference layer 44 in a plane may be smaller than the diameter of the storage layer 42. Moreover, an insulating layer having dimensional differences from the storage layer 42 may be formed as a sidewall of the reference layer 44. Thereby, an electric short between the storage layer 42 and the reference layer 44 can be prevented.

In addition, the order of arrangement may be reversed in the configuration of the magnetoresistive effect element 33. That is, the shift cancelling layer 46, the intermediate layer 45, the second magnetic layer 44C, the nonmagnetic layer 44B, the first magnetic layer 44A, the tunnel barrier layer 43, the storage layer 42, and the underlying layer 41 may be formed in this order on the lower electrode 32.

The lower electrode 32 in the first embodiment comprises a conductive layer containing the first metallic material having a standard electrode potential smaller than that of the second metallic material (for example, Co and Fe) contained in the storage layer 42 and the reference layer 44. The lower electrode 32 will be described in detail below.

FIG. 6 is a graph showing standard electrode potentials of various metallic materials.

As shown in FIG. 6, when the storage layer 42 and the reference layer 44 comprise CoFeB, the lower electrode 32 contains the first metallic material having a standard electrode potential smaller than that of Fe having the smallest standard electrode potential among CoFeB. That is, the standard electrode potential of the first metallic material is smaller than the standard electrode potential (−0.447 V) of Fe. Thus, the first metallic material is a material that is more easily oxidized than Fe. As illustrated, such a first metallic material contains one of Be, Al, Zn, Mg, Yb, Y, Ga, Ca, Eu, Er, Ho, Lu, Zr, Mn, Nd, Sc, Cr, Sr, Tb, Sm, Ce, Dy, Tm, Gd, V, Hf, Ta, Nb, Pa, Ti, and Th or an alloy including at least two of the elements.

In addition, the lower electrode 32 is processed a portion of the surface at an end of thereof at the time of processing of the magnetoresistive effect element 33. Thus, the lower electrode 32 has a step along the plane shape of the magnetoresistive effect element 33. In other words, the top surface at the end of the lower electrode 32 is lower than the top surface in the center portion thereof.

The insulating layer 32B is formed on the side face (perimeter) of the magnetoresistive effect element 33. This insulating layer 32B is obtained by oxidizing processing residue of the lower electrode 32. More specifically, the insulating layer 32B is obtained by oxidizing re-deposits formed by processing the surface of the lower electrode 32 at the time of processing the magnetoresistive effect element 33. That is, the insulating layer 32B is an oxide of the first metallic material contained in the lower electrode 32. In addition, the insulating layer 32B is a re-deposit of the lower electrode 32 and so has a taper shape in which the thickness becomes thinner from the lower electrode 32 toward the upper electrode 34.

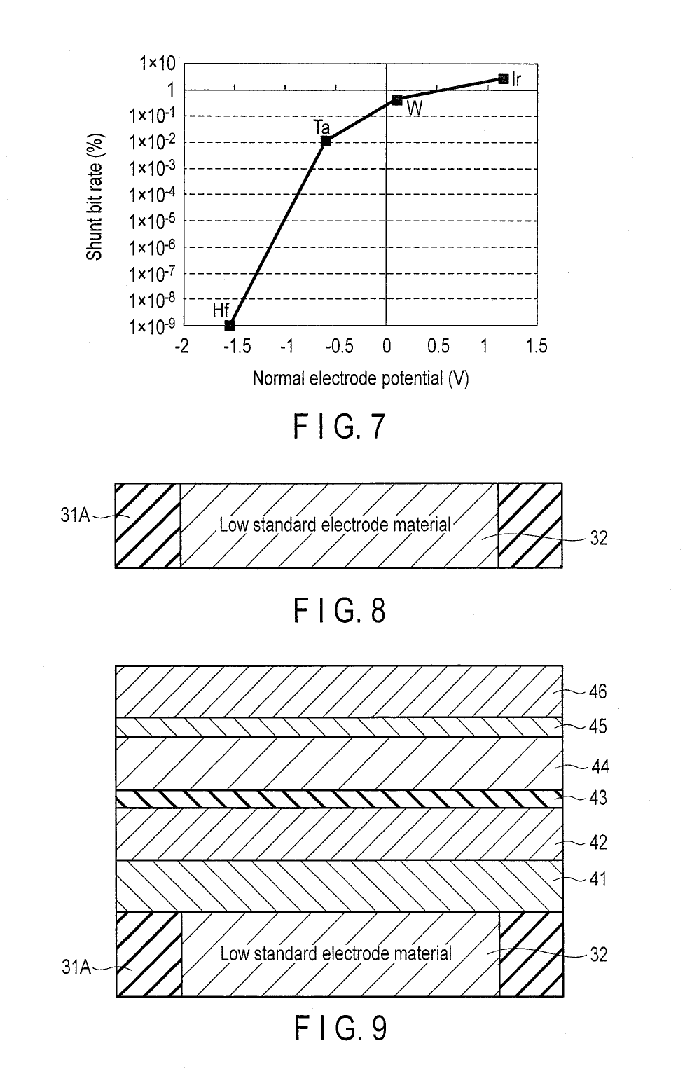

A material having a still lower standard electrode potential is desirable as the first metallic material contained in the lower electrode 32 and the insulating layer 32B. For example, as shown in FIG. 7, Hf having a still lower standard electrode potential has, when compared with Ta, a lower shunt bit rate. From the viewpoint of the shunt bit rate, when compared with Ta, it is desirable to use Hf having a still lower standard electrode potential as the first metallic material.

An insulating layer 47 comprising, for example, SiN, SiO_{X}, MgO, or AlO_{X} is formed on the side face of the insulating layer 32B. The insulating layer 47 functions as a protective layer of the magnetoresistive effect element 33.

[Method of Manufacturing the Magnetoresistive Effect Element According to the First Embodiment]

The method of manufacturing the magnetoresistive effect element 33 according to the first embodiment will be described using FIGS. 8 to 12.

FIGS. 8 to 12 are sectional views showing manufacturing processes of the magnetoresistive effect element according to the first embodiment.

First, as shown in FIG. 8, the interlayer dielectric layer 31A containing, for example, SiO_{X} is formed on the semiconductor substrate 21 by, for example, CVD (Chemical Vapor Deposition) method. Next, a hole not shown reaching the semiconductor substrate 21 is formed in the interlayer dielectric layer 31A by, for example, lithography technology.

Next, the lower electrode 32 is formed in the hole of the interlayer dielectric layer 31A by, for example, CVD method. When the storage layer 42 and the reference layer 44 comprises CoFeB, the lower electrode 32 contains the first metallic material having a standard electrode potential smaller than that of Fe having the smallest standard electrode potential. The first metallic material contains one of Be, Al, Zn, Mg, Yb, Y, Ga, Ca, Eu, Er, Ho, Lu, Zr, Mn, Nd, Sc, Cr, Sr, Tb, Sm, Ce, Dy, Tm, Gd, V, Hf, Ta, Nb, Pa, Ti, and Th or an alloy including at least two of the elements.

Next, as shown in FIG. 9, the underlying layer 41 is formed on the lower electrode 32 and the interlayer dielectric layer 31A by, for example, sputtering method. The underlying layer 41 contains a nonmagnetic material having electric conductivity.

Next, the storage layer 42 is formed on the underlying layer 41 by, for example, sputtering method. The storage layer 42 contains, for example, a ferromagnetic material such as Co and Fe (second metallic material). In addition, B is added to the ferromagnetic material for the purpose of adjusting saturation magnetization or crystal magnetic anisotropy. That is, the storage layer 42 comprises, for example, a compound such as CoFeB.

Next, the tunnel barrier layer 43 is formed on the storage layer 42. The tunnel barrier layer 43 contains, for example, a nonmagnetic material such as MgO. The MgO layer constituting the tunnel barrier layer 43 may be formed by a direct film formation of MgO layer by sputtering method targeting MgO. Moreover, the MgO layer may be formed by forming an Mg layer by sputtering method targeting Mg and then oxidizing the Mg layer. As an oxidation method of the Mg layer, oxidation by oxygen gas, oxygen plasma, oxygen radical, or ozone can be cited. To improve the MR ratio, it is desirable to directly form the MgO layer by the sputtering method targeting MgO. In addition, the MgO layer may be formed by MBE (Molecular Beam Epitaxy) method, the ALD (Atomic Layer Deposition) method, or the CVD method.

Next, the reference layer 44 is formed on the tunnel barrier layer 43 by, for example, sputtering method. The reference layer 44 comprises, for example, a stacked structure of a first magnetic layer, a nonmagnetic layer, and a second magnetic layer formed from the side of the tunnel barrier layer.

The first magnetic layer contains, for example, a ferromagnetic material such as Co and Fe (second metallic material). In addition, B is added to the ferromagnetic material for the purpose of adjusting saturation magnetization or crystal magnetic anisotropy. That is, the first magnetic layer comprises, for example, a compound such as CoFeB same as the storage layer 42. The first magnetic layer is a layer contributing to the MR ratio. The nonmagnetic layer is formed between the first magnetic layer and the second magnetic layer. The nonmagnetic layer contains a nonmagnetic material such as Ta, W, or Hf. The second magnetic layer contains a ferromagnetic material and a nonmagnetic material. For example, Pt can be cited as the nonmagnetic material. As the ferromagnetic material, for example, Co is contained as a ferromagnetic material. That is, the second magnetic layer comprises, for example, a stacked film of a Pt layer and a Co layer. This stacked film comprises a plurality of Pt layers and a plurality of Co layers being alternately stacked. The second magnetic layer contributes to perpendicular magnetic anisotropy. The second magnetic layer as described above is formed by changing the target in the sputtering method.

Next, the intermediate layer 45 made of Ru is formed on the reference layer 44 by, for example, sputtering method, and the shift cancelling layer 46 is formed on this intermediate layer 45 by, for example, sputtering method. The shift cancelling layer 46 comprises an artificial lattice having a stacked structure of a ferromagnetic material like such as Ni, Fe, or Co and a nonmagnetic material such as Cu, Pd, or Pt.

Thereafter, each layer of the magnetoresistive effect element 33 is crystallized by performing annealing.

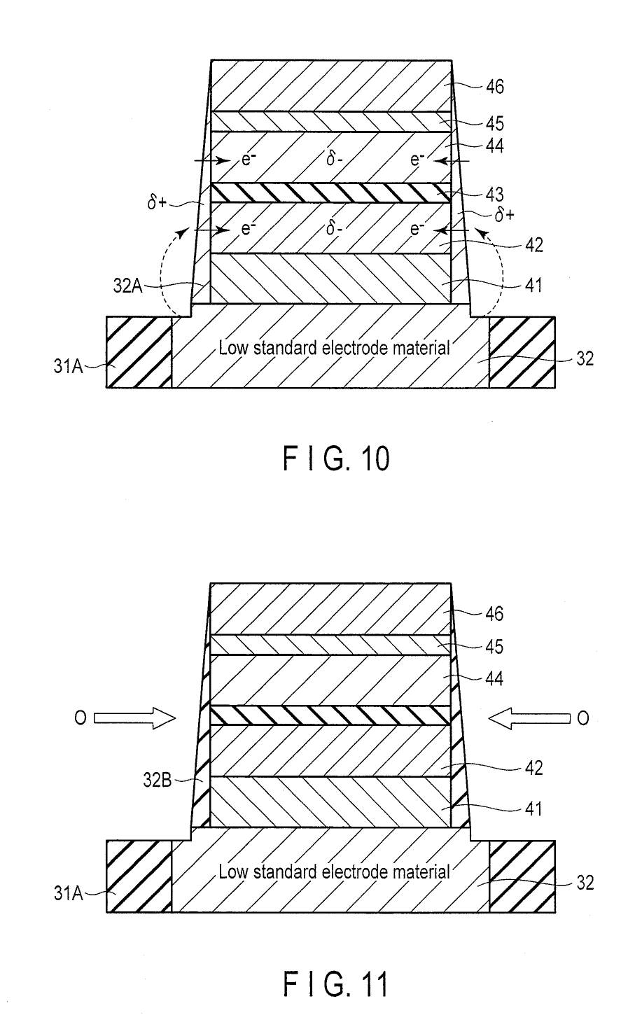

Next, as shown in FIG. 10, a hard mask not shown is formed on the shift cancelling layer 46 and is patterned so that the plane shape thereof is, for example, circular. The hard mask comprises a metallic material having electric conductivity, for example, comprises TiN. The metallic material is not limited to the above example and the hard mask may comprise a film containing one of Ti, Ta, and W or a stacked film thereof. Thereby, the hard mask does not need to be removed later and can be used as a contact portion for the upper electrode 34.

Next, the shift cancelling layer 46, the intermediate layer 45, the reference layer 44, the tunnel barrier layer 43, the storage layer 42, and the underlying layer 41 are processed by physical etching such as ion milling method using the hard mask as a mask. Thereby, the shift cancelling layer 46, the intermediate layer 45, the reference layer 44, the tunnel barrier layer 43, the storage layer 42, and the underlying layer 41 are patterned in the same manner as the hard mask and the plane shape thereof becomes circular.

At this point, down to the surface of the lower electrode 32 is processed. Thereby, the first metallic material contained in the lower electrode 32 is re-deposited on the side face of the magnetoresistive effect element 33, so that the conductive layer 32A is formed. Therefore, the conductive layer 32A contains the first metallic material having a standard electrode potential smaller than that of Fe having the smallest standard electrode potential among CoFeB contained in the storage layer 42 and the reference layer 44. Then, electrons move from the conductive layer 32A to the storage layer 42 and the reference layer 44. As a result, the storage layer 42 and the reference layer 44 are charged at δ− and the conductive layer 32A is charged at δ+.

Next, as shown in FIG. 11, the conductive layer 32A is oxidized by one of various oxidation methods to form an insulating layer 32B. Thus, the insulating layer 32B is an oxide of the first metallic material contained in the lower electrode 32. Oxidation by an oxygen gas, oxygen plasma, oxygen radical, or ozone can be cited as the oxidation method. At this point, the storage layer 42 and the reference layer 44 are charged at δ− and the conductive layer 32A is charged at δ+ and thus, the conductive layer 32A is more likely to be oxidized than the storage layer 42 and the reference layer 44. Therefore, only the conductive layer 32A can be oxidized even by weak oxidation. That is, oxidation of the storage layer 42 and the reference layer 44 by the oxidation process can be suppressed.

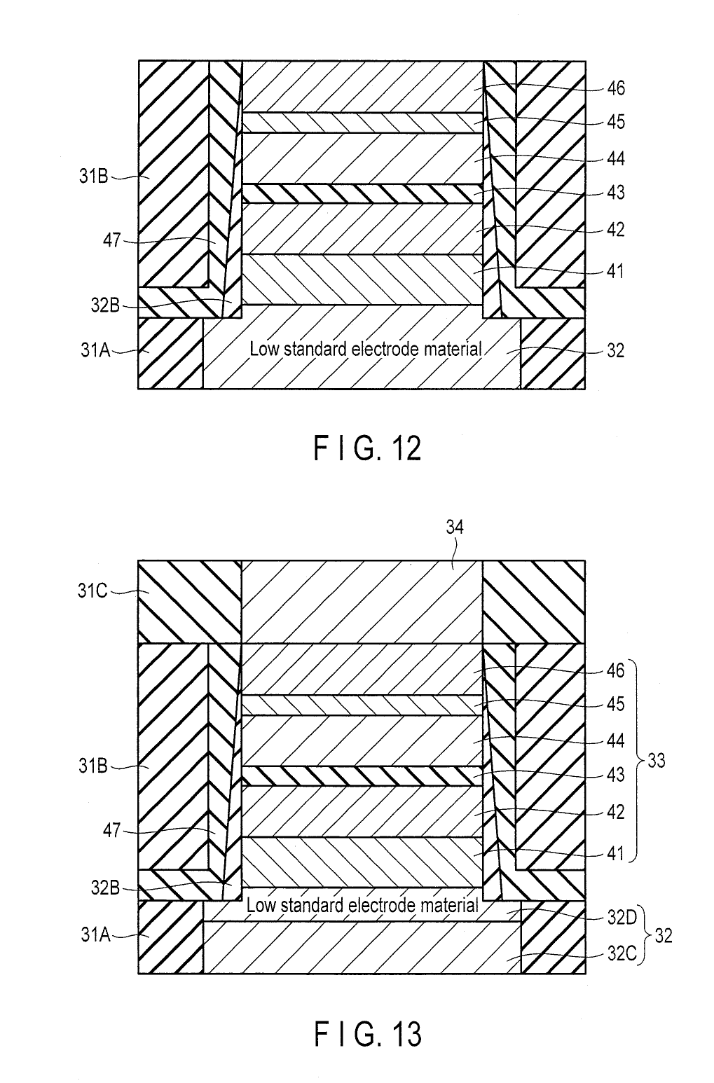

Next, as shown in FIG. 12, the insulating layer 47 comprising, for example, SiN, SiO_{X}, MgO, or AlO_{X} is formed by, for example, sputtering method, CVD method, or ALD method. The insulating layer 47 functions as a protective layer of the magnetoresistive effect element 33 in the next step.

Next, an interlayer dielectric layer 31B containing, for example, SiO_{X} is formed on the entire surface by, for example, CVD method. Thereby, the interlayer dielectric layer 31B is embedded between the neighboring magnetoresistive effect elements 33. Thereafter, the interlayer dielectric layer 31B formed on the magnetoresistive effect elements 33 is etched back after being planarized. Thereby, the top surface of the magnetoresistive effect elements 33 is exposed.

Next, as shown in FIG. 5, the interlayer dielectric layer 31C containing, for example, SiO_{X} is formed on the magnetoresistive effect elements 33 and the interlayer dielectric layer 31B. Next, a hole not shown reaching the magnetoresistive effect elements 33 is formed in the interlayer dielectric layer 31A by, for example, lithography technology. Thereafter, the upper electrode 34 is formed in the hole by, for example, CVD method and electrically connected to the magnetoresistive effect elements 33.

In this manner, the magnetoresistive effect elements 33 according to the first embodiment is formed.

[Effect According to the First Embodiment]

According to the first embodiment described above, the lower electrode 32 positioned below a stacked body includes the storage layer 42, the tunnel barrier layer 43, and the reference layer 44 contains the first metallic material having the standard electrode potential smaller than that of the second metallic material contained in the storage layer 42 and the reference layer 44. Then, the conductive layer 32A containing the first metallic material is re-deposited on the side face of the stacked body by the processing of the lower electrode 32. Because the first metallic material can easily be oxidized, the insulating layer 32B can be formed by oxidizing the conductive layer 32A while oxidation damage to the storage layer 42 and the reference layer 44 being suppressed. That is, degradation of the MR ratio can be suppressed while the short fault in the stacked body is prevented.

[Modification of the First Embodiment]

FIG. 13 is a sectional view showing the configuration of a modification of the magnetoresistive effect element according to the first embodiment.

As shown in FIG. 13, in the modification, the lower electrode 32 comprises a first electrode 32C on the lower side and a second electrode 32D on the upper side. In other words, the second electrode 32D is formed near the surface of the lower electrode 32.

The first electrode 32C contains various conductive materials with high embedding properties. The first electrode 32C contains, for example, TiN, but is not limited to such an example and may contain W.

The second electrode 32D is formed on the first electrode 32C and is formed in contact with the magnetoresistive effect element 33. The second electrode 32D contains the first metallic material, that is, one of Be, Al, Zn, Mg, Yb, Y, Ga, Ca, Eu, Er, Ho, Lu, Zr, Mn, Nd, Sc, Cr, Sr, Tb, Sm, Ce, Dy, Tm, Gd, V, Hf, Ta, Nb, Pa, Ti, and Th or an alloy including at least two of the elements.

When the magnetoresistive effect element 33 is processed, a portion of the surface at an end of the second electrode 32D is processed. Thus, the second electrode 32D has a step along the plane shape of the magnetoresistive effect element 33. In other words, the top surface at the end of the second electrode 32D is lower than the top surface in the center portion thereof.

In this way, according to the modification, the first electrode 32C containing various metallic materials with high embedding properties is formed on the lower side of the lower electrode 32 and the second electrode 32D containing the first metallic material that is easily oxidized is formed only in a portion of the surface on the upper side. Thereby, restrictions of materials in manufacturing processes or the like can be limited to a necessary minimum.

### Second Embodiment

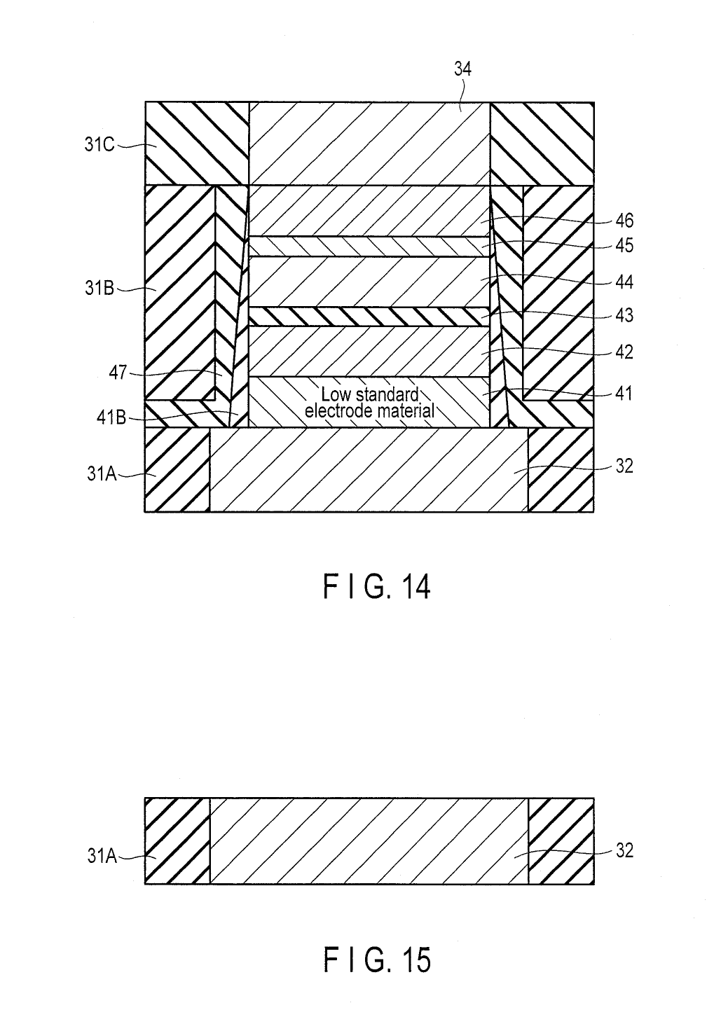

MRAM according to the second embodiment will be described below using FIGS. 14 to 19. In MRAM according to the first embodiment, re-deposition of materials of the lower electrode 32 by the surface of the lower electrode 32 being processed poses a problem. Thus, in the first embodiment, the lower electrode 32 contains the first metallic material having the standard electrode potential smaller than that of the second metallic material contained in the storage layer 42 and the reference layer 44.

However, even if the surface of the lower electrode 32 is not substantially processed (when the minimum is processed), re-deposition of materials of the underlying layer 41 positioned thereon poses a problem.

In the second embodiment, by contrast, the underlying layer 41 contains the first metallic material having a standard electrode potential smaller than that of the second metallic material contained in the storage layer 42 and the reference layer 44. Thereby, even if the processing residue of the underlying layer 41 is re-deposited on the side face of a stacked body, the re-deposit can easily be oxidized. The second embodiment will be described in detail below.

In the second embodiment, the description similar to that in the first embodiment is omitted and differences will mainly be described.

[Configuration of the Magnetoresistive Effect Element According to the Second Embodiment]

The configuration of the magnetoresistive effect element 33 according to the second embodiment will be described using FIG. 14.

FIG. 14 is a sectional view showing the configuration of the magnetoresistive effect element according to the second embodiment. Here, in addition to the magnetoresistive effect element 33, the lower electrode 32 positioned below the magnetoresistive effect element 33 and the upper electrode 34 positioned above the magnetoresistive effect element 33 are also shown.

As shown in FIG. 14, the difference of the second embodiment from the first embodiment is that the underlying layer 41 contains the first metallic material having the standard electrode potential smaller than that of the second metallic material contained in the storage layer 42 and the reference layer 44.

More specifically, when the storage layer 42 and the reference layer 44 comprise CoFeB, the underlying layer 41 in the second embodiment contains the first metallic material having a standard electrode potential smaller than that of Fe having the smallest standard electrode potential among CoFeB. That is, the standard electrode potential of the first metallic material is smaller than the standard electrode potential (−0.447 V) of Fe. Thus, the first metallic material is a material that is more easily oxidized than Fe. The first metallic material as described above contains one of Be, Al, Zn, Mg, Yb, Y, Ga, Ca, Eu, Er, Ho, Lu, Zr, Mn, Nd, Sc, Cr, Sr, Tb, Sm, Ce, Dy, Tm, Gd, V, Hf, Ta, Nb, Pa, Ti, and Th or an alloy including at least two of the elements.

An insulating layer 41B is formed on the side face (perimeter) of the magnetoresistive effect element 33. The insulating layer 41B is obtained by oxidizing processing residue of the underlying layer 41. More specifically, the insulating layer 41B is obtained by oxidizing re-deposits formed by processing the underlying layer 41 when the magnetoresistive effect element 33 is processed. That is, the insulating layer 41B is an oxide of the first metallic material contained in the underlying layer 41. In addition, the insulating layer 41B is a re-deposit of the underlying layer 41 and so has a taper shape in which the thickness becomes thinner from the lower side toward the upper side.

A material having a still lower standard electrode potential is desirable as the first metallic material contained in the underlying layer 41 and the insulating layer 41B. For example, as shown in FIG. 7, Hf having a still lower standard electrode potential has, when compared with Ta, a lower shunt bit rate. From the viewpoint of the shunt bit rate, when compared with Ta, it is desirable to use Hf having a still lower standard electrode potential as the first metallic material.

The lower electrode 32 contains various conductive materials with high embedding properties. The lower electrode 32 contains, for example, TiN, but is not limited to such an example and may contain W. In addition, when the magnetoresistive effect element 33 is processed, the lower electrode 32 is substantially not processed. Thus, the top surface of the lower electrode 32 is substantially flat.

[Method of Manufacturing the Magnetoresistive Effect Element According to the Second Embodiment]

The method of manufacturing the magnetoresistive effect element 33 according to the second embodiment will be described using FIGS. 15 to 19.

FIGS. 15 to 19 are sectional views showing manufacturing processes of the magnetoresistive effect element according to the second embodiment.

First, as shown in FIG. 15, the interlayer dielectric layer 31A containing, for example, SiO_{X} is formed on the semiconductor substrate 21 by, for example, CVD method. Next, a hole not shown reaching the semiconductor substrate 21 is formed in the interlayer dielectric layer 31A by, for example, lithography technology.

Next, the lower electrode 32 is formed in the hole of the interlayer dielectric layer 31A by, for example, CVD method. The lower electrode 32 contains various conductive materials with high embedding properties. The lower electrode 32 contains, for example, TiN, but is not limited to such an example and may contain W.

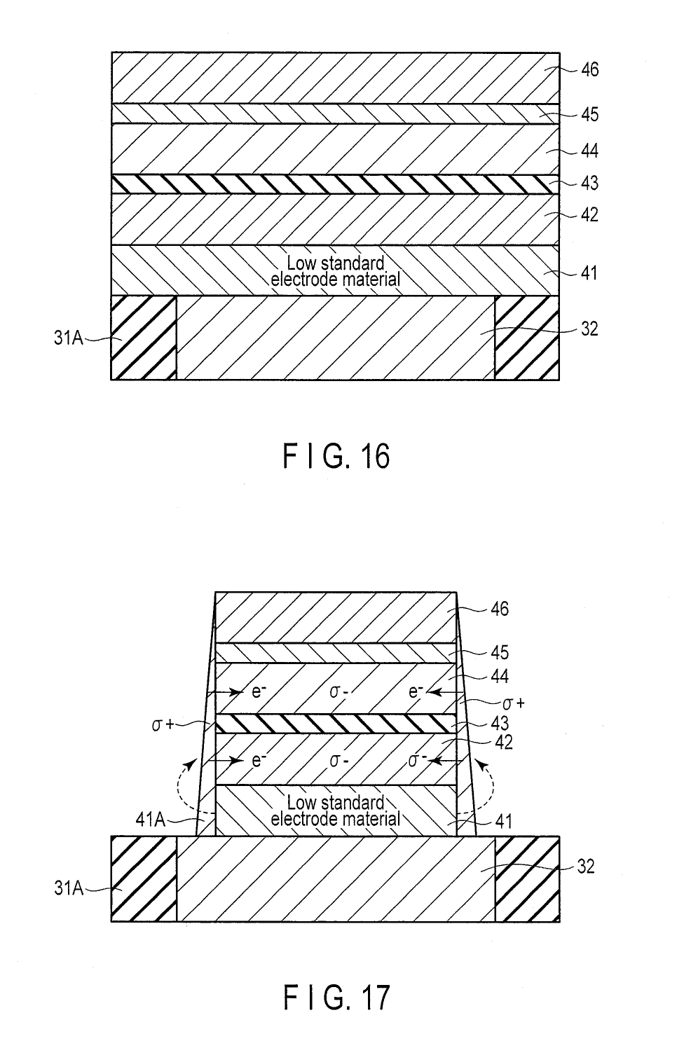

Next, as shown in FIG. 16, the underlying layer 41 is formed on the lower electrode 32 and the interlayer dielectric layer 31A by, for example, sputtering method. When the storage layer 42 and the reference layer 44 comprise CoFeB, the underlying layer 41 contains the first metallic material having a standard electrode potential smaller than that of Fe having the smallest standard electrode potential. The first metallic material contains one of Be, Al, Zn, Mg, Yb, Y, Ga, Ca, Eu, Er, Ho, Lu, Zr, Mn, Nd, Sc, Cr, Sr, Tb, Sm, Ce, Dy, Tm, Gd, V, Hf, Ta, Nb, Pa, Ti, and Th or an alloy including at least two of the elements.

Thereafter, like in the first embodiment, the storage layer 42, the tunnel barrier layer 43, the reference layer 44, the intermediate layer 45, and the shift cancelling layer 46 are formed in this order on the underlying layer 41. Next, each layer of the magnetoresistive effect element 33 is crystallized by performing annealing.

Next, as shown in FIG. 17, a hard mask not shown is formed on the shift cancelling layer 46 and patterned so that the plane shape thereof is, for example, circular. Thereafter, the shift cancelling layer 46, the intermediate layer 45, the reference layer 44, the tunnel barrier layer 43, the storage layer 42, and the underlying layer 41 are processed by physical etching such as ion milling method using the hard mask as a mask. Thereby, the shift cancelling layer 46, the intermediate layer 45, the reference layer 44, the tunnel barrier layer 43, the storage layer 42, and the underlying layer 41 are patterned in the same manner as the hard mask and the plane shape thereof becomes circular.

At this point, even if the surface of the lower electrode 32 is substantially not processed, a conductive layer 41A is formed on the side face of the magnetoresistive effect element 33 by the first metallic material contained in the underlying layer 41 being re-deposited thereon. Therefore, the conductive layer 41A contains the first metallic material having the standard electrode potential smaller than that of Fe having the smallest standard electrode potential among CoFeB contained in the storage layer 42 and the reference layer 44. Then, electrons move from the conductive layer 41A to the storage layer 42 and the reference layer 44. As a result, the storage layer 42 and the reference layer 44 are charged at δ− and the conductive layer 41A is charged at δ+.

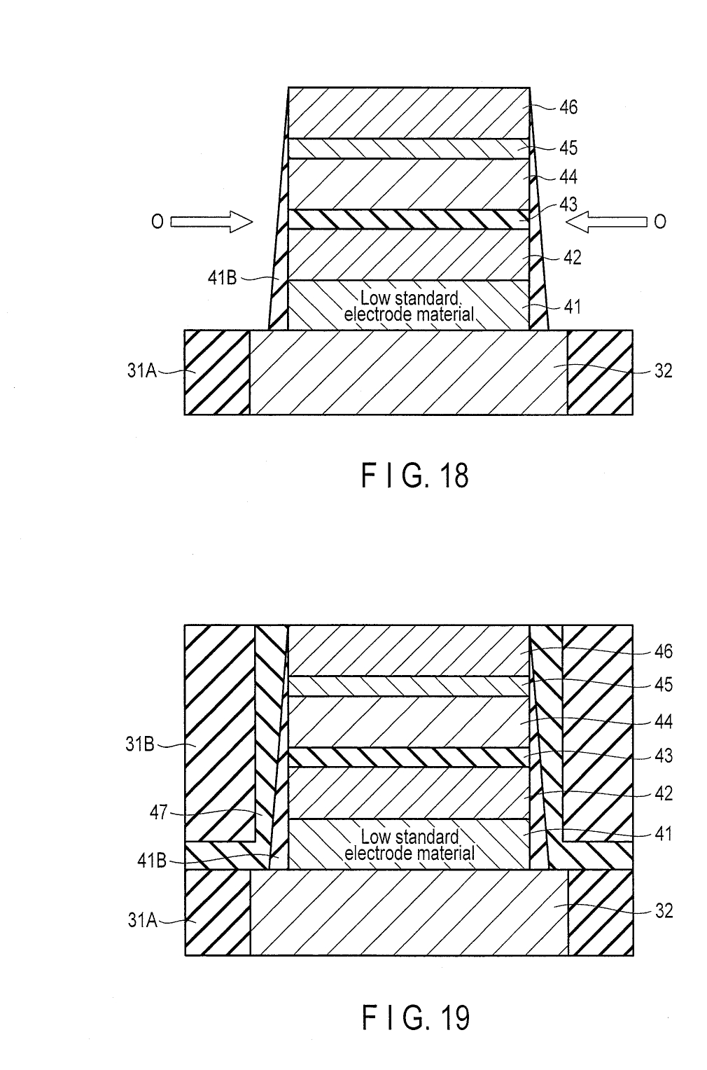

Next, as shown in FIG. 18, the conductive layer 41A is oxidized by one of various oxidation methods to form the insulating layer 41B. Thus, the insulating layer 41B is an oxide of the first metallic material contained in the lower electrode 32. Oxidation by an oxygen gas, oxygen plasma, oxygen radical, or ozone can be cited as the oxidation method. At this time, the storage layer 42 and the reference layer 44 are charged at 6- and the conductive layer 41A is charged at 6+ and thus, the conductive layer 41A is more likely to be oxidized than the storage layer 42 and the reference layer 44. Therefore, only the conductive layer 41A can be oxidized even by weak oxidation. That is, oxidation of the storage layer 42 and the reference layer 44 by the oxidation process can be suppressed.

Next, like in the first embodiment, as shown in FIG. 19, the insulating layer 47 and the interlayer dielectric layer 31B are formed. Thereby, the interlayer dielectric layer 31B is embedded between the neighboring magnetoresistive effect elements 33. Thereafter, the top surface of the magnetoresistive effect element 33 is exposed, then, as shown in FIG. 5, the interlayer dielectric layer 31C is formed. Next, a hole not shown reaching the magnetoresistive effect element 33 is formed in the interlayer dielectric layer 31A and the upper electrode 34 is formed in the hole and electrically connected to the magnetoresistive effect element 33.

In this manner, the magnetoresistive effect elements 33 according to the second embodiment is formed.

[Effect According to the Second Embodiment]

According to the second embodiment described above, the underlying layer 41 positioned below a stacked body comprising the storage layer 42, the tunnel barrier layer 43, and the reference layer 44 contains the first metallic material having the standard electrode potential smaller than that of the second metallic material contained in the storage layer 42 and the reference layer 44. Then, even if the lower electrode 32 is substantially not processed, the conductive layer 41A containing the first metallic material is re-deposited on the side face of the stacked body by the processing of the underlying layer 41. Because the first metallic material can easily be oxidized, the insulating layer 41B can be formed by oxidizing the conductive layer 41A while oxidation damage to the storage layer 42 and the reference layer 44 being suppressed. That is, degradation of the MR ratio can be suppressed while the short fault in the stacked body is prevented.

### Third Embodiment

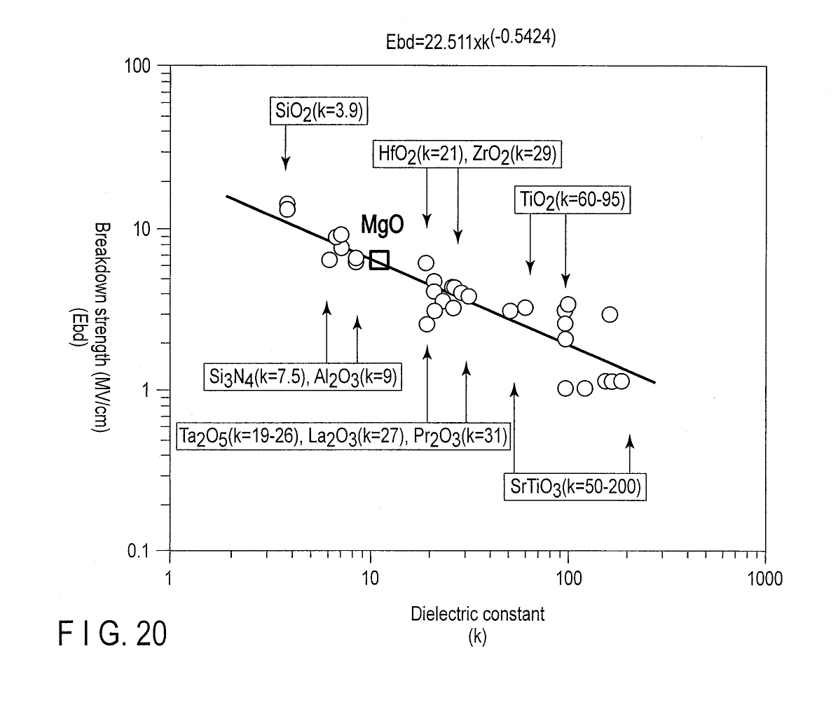

MRAM according to a third embodiment will be described below using FIGS. 20 to 22.

When, for example, Ta is used as the underlying layer 41, the insulating layer 41B made of an oxide (Ta₂O₅) of Ta (re-deposit) is formed on the side face of the magnetoresistive effect element 33. The dielectric constant of Ta₂O₅ is 24 which is larger than the dielectric constant 9.65 of MgO used in the tunnel barrier layer 43. As will be described later, the breakdown field decreases with an increasing of dielectric constant. That is, the breakdown field of Ta₂O₅ is smaller than the breakdown field of MgO. Thus, even if a short fault is prevented by oxidizing a re-deposit, the withstand voltage is degraded if the breakdown field of oxide of the re-deposit is smaller than that of MgO. In addition, electronic polarization increases and thus, a leak current via a re-deposit is more likely to flow and the breakdown field decreases.

In contrast, the third embodiment is a modification of the second embodiment and an example of suppressing degradation of the breakdown field due to a re-deposit by limiting the dielectric constant of oxide of the first metallic material contained in the underlying layer 41 in accordance with the thickness of the tunnel barrier layer 43. The third embodiment will be described in detail below.

In the third embodiment, the description similar to that in the second embodiment is omitted and differences will mainly be described.

[Dielectric Constant of Oxide of the First Metallic Material Contained in the Underlying Layer According to the Third Embodiment]

The dielectric constant of oxide of the first metallic material contained in the underlying layer 41 according to the third embodiment will be described using FIGS. 20 to 22.

FIG. 20 is a graph showing the relationship between the dielectric constant and the breakdown field of various oxides.

As shown in FIG. 20, the dielectric constant k and the breakdown field Ebd [MV/cm] of various oxides have the relationship of Formula (1).

Ebd=22.511×k^{(-0.5424)} (1)

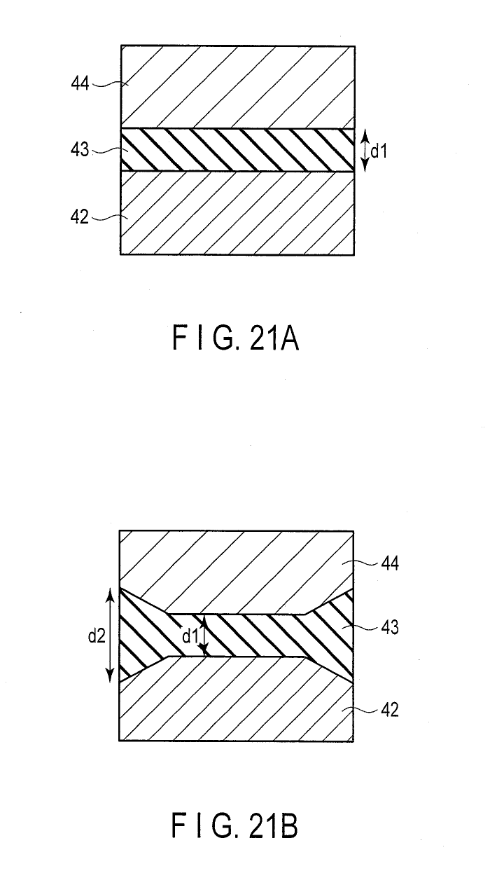

FIGS. 21A and 21B are sectional views illustrating the thickness of the tunnel barrier layer 43. More specifically, FIG. 21A is a diagram showing the ideal thickness of tunnel barrier layer 43 after the oxidation process of a re-deposit and FIG. 21B is a diagram showing the actual thickness of the tunnel barrier layer 43 after the oxidation process of the re-deposit.

As shown in FIG. 21A, the thickness of the tunnel barrier layer 43 is a uniform thickness d1 after the ideal processing of the magnetoresistive effect element 33. However, as shown in FIG. 21B, in the actual processing of the magnetoresistive effect element 33, the oxidation region increases under the influence of the oxidation step of the re-deposit. Thus, the thickness of the tunnel barrier layer 43 increases near the end thereof. That is, while the thickness of the tunnel barrier layer 43 is the thickness d1 in the center portion, the thickness thereof at an end is a thickness d2, which is thicker than the thickness d1. A breakdown field Ebd2 to be satisfied at an end of the tunnel barrier layer 43 is represented by formula (2) using the breakdown field Ebd1 in the center portion.

Ebd2=(d1/d2)Ebd1 (2)

As shown in Formula (2), the breakdown field Ebd2 at an end of the tunnel barrier layer 43 can be smaller as the thickness thereof increases. In other words, with an increasing thickness at an end of the tunnel barrier layer 43, the distance between electrodes, that is between the storage layer 42 and the reference layer 44 increases. Thereby, the breakdown field Ebd2 at an end of a large thickness may be smaller than the breakdown field Ebd1 in the center portion which has a small thickness.

Here, in order to prevent the decreasing of breakdown field due to the re-deposit, a breakdown field Ebd3 of oxide (insulating layer 41B) of the re-deposit needs to be equal to or more than the breakdown field Ebd2 at the end in the tunnel barrier layer 43. Thus, from formulas (1) and (2), formula (3) holds for the breakdown field Ebd3.

Ebd3=22.511×k^{(-0.5424)}≧(d1/d2)Ebd1 (3)

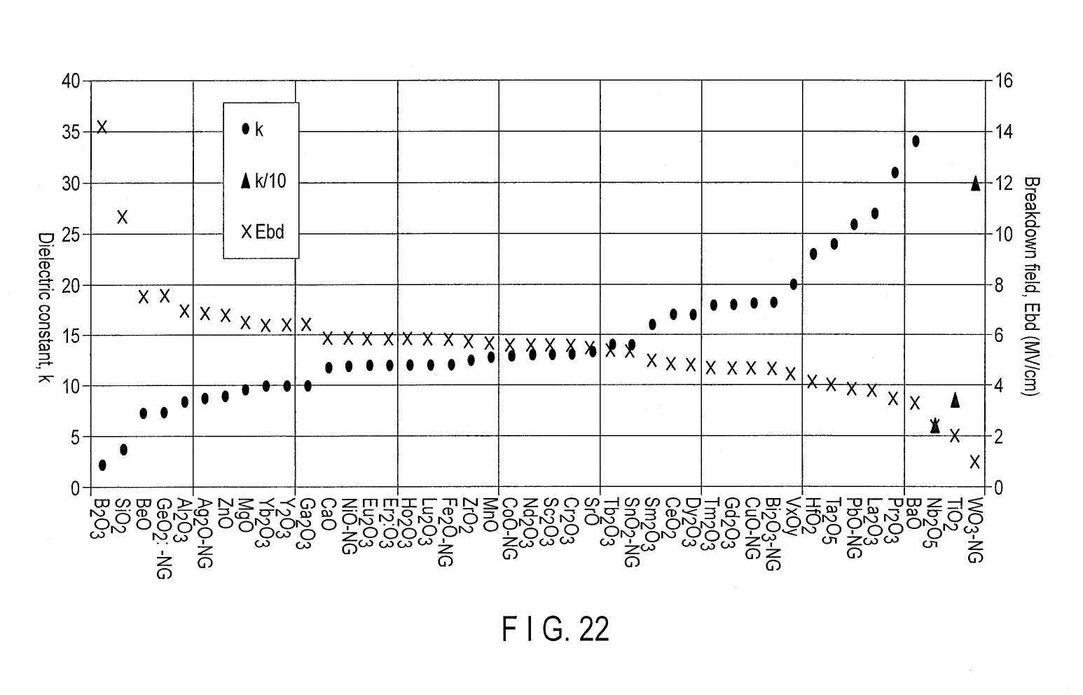

FIG. 22 is a diagram showing the dielectric constants and breakdown fields of various oxides. Here, each breakdown field is calculated from formula (1). “NG” in FIG. 22 indicates that the standard electrode potential in the second embodiment is not in the allowable range.

In order for the insulating layer 41B to satisfy formula (3), similarly an oxide of the first metallic material contained in the underlying layer 41 needs to satisfy formula (3).

For example, when the tunnel barrier layer 43 has the ideal thickness shown in FIG. 21A, the insulating layer 41B (oxide of the first metallic material) needs to have a dielectric constant equal to or less a dielectric constant of MgO. That is, as shown in FIG. 22, it is desirable to use Be, Zn, or Al as the first metallic material. It is noted that Ga, Y, or Yb may be all right since it has a dielectric constant approximately equal to that of MgO.

As described above, actually, the tunnel barrier layer 43 has the shape shown in FIG. 21B, the allowable range of the dielectric constant of oxide of the first metallic material broadens. More specifically, the dielectric constant of oxide of the first metallic material may be larger than that of MgO. In addition, the allowable range of the dielectric constant of oxide of the first metallic material broadens as the thickness of the tunnel barrier layer 43 increases. Thus, the first metallic material may be Be, Al, Zn, Mg, Yb, Y, Ga, Ca, Eu, Er, Ho, Lu, Zr, Mn, Nd, Sc, Cr, Sr, Tb, Sm, Ce, Dy, Tm, Gd, V, or Hf.

In addition, the underlying layer 41 may contain a nitride or boride of the first metallic material.

Particularly, the underlying layer 41 desirably contains a boride of the first metallic material. This is because of the following reason. When the underlying layer 41 contains the boride of the first metallic material, boron atoms become boron oxide (B₂O₃) after the processing step of the magnetoresistive effect element 33 and the oxidation step of a re-deposit. Then, boron oxide (B₂O₃) is formed on the side face of the tunnel barrier layer 43 together with oxide of the first metallic material. In other words, the insulating layer 41B contains the oxide of the first metallic material and B₂O₃. As shown in FIG. 22, B₂O₃ has a larger breakdown field than MgO. As a result, the breakdown field can be made larger than a case where only the oxide of the first metallic material is formed.

On the other hand, when the underlying layer 41 contains a nitride of the first metallic material, nitrogen atoms are desorbed from the magnetoresistive effect element 33 after the processing step of the magnetoresistive effect element 33 and the oxidation step of a re-deposit. Thus, only the oxide (insulating layer 42B) of the first metallic material is formed on the side face of the tunnel barrier layer 43. That is, this is the same as in a case where the underlying layer 41 contains the first metallic material.

[Effect According to the Third Embodiment]

According to the third embodiment described above, the dielectric constant of oxide of the first metallic material contained in the underlying layer 41 is limited in accordance with the thickness at the end of the tunnel barrier layer 43. More specifically, control is exercised so that the above formula (3) holds. Thereby, the reduction of breakdown field due to the oxide of a re-deposit (insulating layer 41B) caused by the underlying layer 41 can be suppressed.

In the present example, the limitation of dielectric constant in the third embodiment is applied to the underlying layer 41 in the second embodiment, but it is not limited to such an example. The limitation of dielectric constant in the third embodiment can also be applied to the lower electrode 32 in the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory comprising:
a conductive layer containing a first metallic material;
a stacked body formed above the conductive layer and comprising a first magnetic layer containing a second metallic material, a second magnetic layer, and a tunnel barrier layer formed between the first magnetic layer and the second magnetic layer; and
an insulating layer formed on a side face of the stacked body and containing an oxide of the first metallic material, wherein
a standard electrode potential of the first metallic material is lower than the standard electrode potential of the second metallic material.

2. The memory of claim 1, wherein
the conductive layer is a lower electrode in contact with a semiconductor substrate.

3. The memory of claim 1, wherein
the conductive layer is a portion of a lower electrode in contact with a semiconductor substrate.

4. The memory of claim 1, wherein
the conductive layer is an underlying layer in contact with the stacked body.

5. The memory of claim 1, wherein
the second metallic material contains Fe.

6. The memory of claim 5, wherein
the first metallic material contains one of Be, Al, Zn, Mg, Yb, Y, Ga, Ca, Eu, Er, Ho, Lu, Zr, Mn, Nd, Sc, Cr, Sr, Tb, Sm, Ce, Dy, Tm, Gd, V, Hf, Ta, Nb, Pa, Ti, and Th, or contains an alloy including at least two of the elements.

7. The memory of claim 1, wherein
a thickness d1 in a center portion of the tunnel barrier layer, a thickness d2 (d1<d2) at an end of the tunnel barrier layer, a breakdown field Ebd1 in the center portion of the tunnel barrier layer, and a dielectric constant k of the oxide of the first metallic material have a relationship of a formula (3) below.
22.511×k^{(-0.5424)}—(d1/d2)Ebd1 (3)

8. The memory of claim 1, wherein
the conductive layer contains a boride of the first metallic material.

9. The memory of claim 8, wherein
the insulating layer contains a boron oxide.

10. The memory of claim 1, wherein
the conductive layer contains a nitride of the first metallic material.

11. A magnetic memory comprising:
a conductive layer containing a first metallic material;
a stacked body including a first magnetic layer formed above the conductive layer and comprising a second metallic material, a second magnetic layer, and a tunnel barrier layer formed between the first magnetic layer and the second magnetic layer;
an insulating layer formed on a side face of the stacked body and containing an oxide of the first metallic material, wherein
a thickness d1 in a center portion of the tunnel barrier layer, a thickness d2 (d1<d2) at an end of the tunnel barrier layer, a breakdown field Ebd1 in the center portion of the tunnel barrier layer, and a dielectric constant k of the oxide of the first metallic material have a relationship of a formula (3) below.
22.511×k^{(-0.5424)}≧(d1/d2)Ebd1 (3)

12. The memory of claim 11, wherein
the conductive layer is a lower electrode in contact with a semiconductor substrate.

13. The memory of claim 11, wherein
the conductive layer is a portion of a lower electrode in contact with a semiconductor substrate.

14. The memory of claim 11, wherein
the conductive layer is an underlying layer in contact with the stacked body.

15. The memory of claim 11, wherein
the second metallic material contains Fe.

16. The memory of claim 15, wherein
the first metallic material contains one of Be, Al, Zn, Mg, Yb, Y, Ga, Ca, Eu, Er, Ho, Lu, Zr, Mn, Nd, Sc, Cr, Sr, Tb, Sm, Ce, Dy, Tm, Gd, V, Hf, Ta, Nb, Pa, Ti, and Th, or contains an alloy including at least two of the elements.

17. The memory of claim 11, wherein
the conductive layer contains a boride of the first metallic material.

18. The memory of claim 17, wherein
the insulating layer contains a boron oxide.

19. The memory of claim 11, wherein
the conductive layer contains a nitride of the first metallic material.

20. A method of manufacturing a magnetic memory comprising:
forming a first conductive layer containing a first metallic material;
forming a stacked body comprising a first magnetic layer containing a second metallic material, a second magnetic layer, and a tunnel barrier layer formed between the first magnetic layer and the second magnetic layer, above the first conductive layer;
forming a second conductive layer containing the first metallic material on a side face of the stacked body by processing the stacked body and the conductive layer; and
forming an insulating layer containing an oxide of the first metallic material by oxidizing the second conductive layer, wherein
a standard electrode potential of the first metallic material is lower than a standard electrode potential of the second metallic material.
